(19) United States
(12) Patent Application Publication
(10) Pub. No.: US 2025/0071884 A1
(43) Pub. Date: Feb. 27, 2025

(54) ADDITIVE MANUFACTURED COAX-LIKE CONNECTION FOR MICROSTRIP ANTENNA FEEDING AND SIGNAL INTEGRITY IN HIGH FREQUENCY PCB

(71) Applicant: Rockwell Collins, Inc., Cedar Rapids, IA (US)

(72) Inventors: Luca Manica, Trento (IT); Carlo L. Tiana, Goldendale, WA (US)

(21) Appl. No.: 18/804,932

(22) Filed: Aug. 14, 2024

(30) Foreign Application Priority Data
Aug. 21, 2023 (EP) 23425040.5

(51) Int. Cl. H05K 1/02; H01Q 9/04; H01R 9/05

(52) U.S. Cl. CPC H05K 1/0243; H01Q 9/0407; H01R 9/0515; H01R 2201/02; H01R 2201/24; H05K 2201/10098

(57) ABSTRACT

A printed circuit board “PCB” comprising a coaxial-like connection (210) is described herein. The coaxial-like connection (210) is configured to transmit a radio frequency signal or signals. The PCB can be used in combination with an antenna.

### CROSS-REFERENCE TO RELATED APPLICATIONS

The present application claims the benefit of European Patent Application No. 23425040.5, filed Aug. 21, 2023, which is incorporated herein by reference in the entirety.

### FIELD

The examples described herein relate to the technical field of electrical connections in printed circuit boards (PCBs) such as microstrip lines that are used for feeding patch antennas.

### BACKGROUND

Microstrip patch antennas used in Printed Circuit Boards (PCB) are typically fed using microstrip lines, vias, or apertures, however, at high frequencies all those techniques introduce high power losses and are susceptible to internal (i.e., cross-talk) and external interferences. Additionally, impedance matching using vias is complicated and highly impacted by manufacturing tolerances leading to unpredictable antenna system behaviour.

### SUMMARY

A printed circuit board “PCB” is described herein. In embodiments, the PCB includes a coaxial-like connection, the coaxial-like connection being configured to transmit a radio frequency “RF” signal or signals.

In some examples, the coaxial-like connection may be manufactured via a 3D printing technique or techniques.

In some examples, the coaxial-like connection may be manufactured via an additive manufacturing technique.

In some examples, the PCB may further include an antenna, where the antenna includes a first dielectric layer having first upper surface, an opposite second lower surface and a metal patch provided on the first upper surface of the first dielectric layer, a second dielectric layer having an additional first upper surface and an additional second opposite lower surface and a ground plane provided between the second lower surface of the first dielectric layer and the additional first upper surface of the second dielectric layer, and the coaxial-like connection being provided embedded in the ground plane, the coaxial-like connection being connected to the metal patch to thereby transmit RF power to the metal patch in use.

In some examples, the ground plane may be in direct contact with the second lower surface of the first dielectric layer and in direct contact with the first upper surface of the second dielectric layer.

In some examples, a surface connector may be provided on and attached to the first upper surface of the first dielectric layer via the surface mount connector.

In some examples, the coaxial-like connection may connect the surface mount connector to the metal patch.

In some examples, the PCB may further include first and second coax pins embedded in the ground plane, the first and second coax pins being configured to receive and output the RF signals in use.

In some examples, the PCB may be manufactured via an additive manufacturing technique.

A method of manufacturing a printed circuit board “PCB” is also described herein. In embodiments, the method includes forming a coaxial-like connection in the PCB via a 3D printing technique or techniques.

In some examples, the method may further include forming the coaxial-like connection via an additive manufacturing technique or techniques.

In some examples, the method may further include forming an antenna for the PCB, the method may further include providing a first dielectric layer having a first upper surface and a second opposite lower surface, and providing a metal patch on the first upper surface of the first dielectric layer, providing a second dielectric layer having an additional first upper surface and an additional second opposite lower surface and providing a ground plane provided between the second lower surface of the first dielectric layer and the additional first upper surface of the second dielectric layer, and embedding a coaxial-like probe in the ground plane, and connecting the coaxial-like connection to the metal patch to thereby transmit RF power to the metal patch in use.

In some examples, the method may further include providing the ground plane such that it is in direct contact with the second lower surface of the first dielectric layer and in direct contact with the additional first upper surface of the second dielectric layer.

In some examples, the method may further include providing and attaching a surface mount connector to the first upper surface of the first dielectric layer via the surface mount connector.

In some examples, the method may further include connecting the coaxial-like connection via the surface mount connector to the metal patch.

In some examples, the method may further include embedding first and second coax pins in the ground plane, the first and second coax pins being configured to receive and output the RF signals in use.

In some examples, any or all of the method steps may be performed via an additive manufacturing technique or techniques.

### BRIEF DESCRIPTION OF THE DRAWINGS

FIG. 1a depicts a side view of a prior art microstrip patch antenna.

FIG. 1b depicts a top view of the prior art microstrip patch antenna of FIG. 1a.

FIG. 2 depicts a metal patch antenna with a coaxial probe feed.

FIG. 3 depicts a metal patch antenna with a microstrip line feed.

FIG. 4 depicts a metal patch antenna with a proximity coupled feed.

FIG. 5 depicts a metal patch antenna with an aperture coupled feed.

FIG. 6 depicts a microstrip line with a “via” connection.

FIG. 7 depicts an example of a new type of feeding design, using a coaxial-like connection instead of a microstrip, in accordance with one or more embodiments of the disclosure.

FIG. 8 depicts a connector that may be used in conjunction with the design of FIG. 7, in accordance with one or more embodiments of the disclosure.

FIG. 9 depicts a top view of the PCB of FIG. 7, in accordance with one or more embodiments of the disclosure.

FIG. 10 shows a three-dimensional (3D) view of the PCB of FIG. 9, in accordance with one or more embodiments of the disclosure.

FIG. 11 depicts a side cross sectional view of the PCB of FIGS. 7, 9 and 10, in accordance with one or more embodiments of the disclosure.

FIG. 12 depicts how the coaxial-like connection may be fed into the PCB, in accordance with one or more embodiments of the disclosure.

FIG. 13 depicts how the coaxial-like connection may be fed into the PCB, in accordance with one or more embodiments of the disclosure.

FIG. 14 depicts a top view of a single patch-circular coaxial-like connection, in accordance with one or more embodiments of the disclosure.

FIG. 15 depicts side cross sectional views of the single patch-circular coaxial-like connection, in accordance with one or more embodiments of the disclosure.

FIG. 16 depicts a top view of a single patch square coaxial-like connection, in accordance with one or more embodiments of the disclosure.

FIG. 17 depicts side views of a single patch square coaxial-like connection, in accordance with one or more embodiments of the disclosure.

FIG. 18 depicts a hexagonal patch antenna array, in accordance with one or more embodiments of the disclosure.

FIG. 19 depicts a hexagonal patch antenna array, in accordance with one or more embodiments of the disclosure.

### DETAILED DESCRIPTION

Described herein is a novel method and structure for providing a connection for transmitting radio frequency (RF) signals in a printed circuit board (PCB). This is achieved by providing a PCB using a coaxial-like connection instead of the known connections, as outlined above in the background section. This new type of coaxial-like connection provides a novel way for transmitting RF signals in PCB boards, thereby reducing interferences and impedance mismatch and having broad-band behavior. It is also much more robust to external and on-board interference. This can be manufactured only using 3D printing techniques.

Examples of a new type of electrical connection/electrical feeding means will now be described. These new connecting means may be configured for use between the elements of a printed circuit board (PCB). The connection means has the final appearance of a coaxial-cable embedded in the PCB and it may be used for feeding microstrip patch antennas and in general for carrying high-frequency signals.

In the examples shown and described herein, the connection means may be used for providing an electrical connection to a patch antenna in a printed circuit board (PCB), however, the examples described herein are not limited to being connected to antennas and can be used to connect other electronic components of a PCB.

The new electrical connection means may include a coaxial-cable-like connection that may be used for feeding microstrip antennas and in general for carrying high-frequency signals in a PCB board. The coaxial cable connection means consists of includes an inner conductor surrounded by a conducting shield, with the two separated by an insulating material (e.g., dielectric) as for a coaxial cable. Connector dimensions (i.e., diameters) may be selected for matching antenna impedance in the working frequency band. The whole system may be additive manufactured since, at present, it is impossible to build such antennas using traditional PCB techniques (i.e., lithography). Additionally, using additive manufacturing techniques also means that the final PCB board can take any form (i.e., curvatures) subject to certain physical constraints.

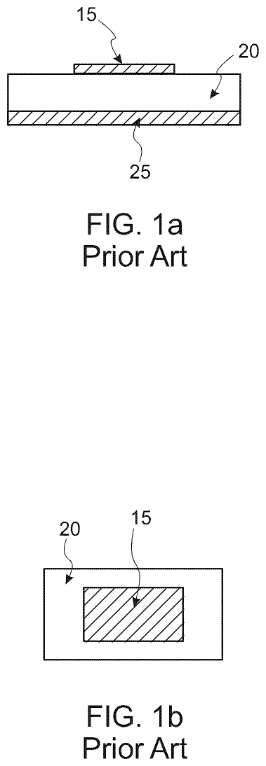

A side view and a top view of a known type of patch antenna is shown in FIGS. 1a and 1b respectively. Such known patch antennas include a metal patch 15 that is provided on top of a dielectric substrate 20 and a ground plane 25, where the dielectric substrate 20 is in combination with the ground plane 25 thereby providing a grounded dielectric substrate. Patches 15 can be of different shapes, where rectangular and circular are the most common. Patch antennas are the most used antenna typology for cm-wave length spectrum. The dielectric layer 20 is provided between the ground plane, or substrate 25, and the metal patch antenna 15 as shown in FIG. 1a.

This type of antenna has various advantages in that it has a low profile and is easy to fabricate (e.g., this can be made via etching and photolithography). It is also easy to feed (e.g., using a coaxial cable, or microstrips) and can be easily integrated into a PCB. The pattern of the metal patch antenna 15 is almost hemispherical and it is easy to use as an element in an antenna array. Patch antennas, however, have some disadvantages also, in that they typically have a low bandwidth, a low efficiency (due to conductors and dielectric losses) and cannot handle a large amount of RF power.

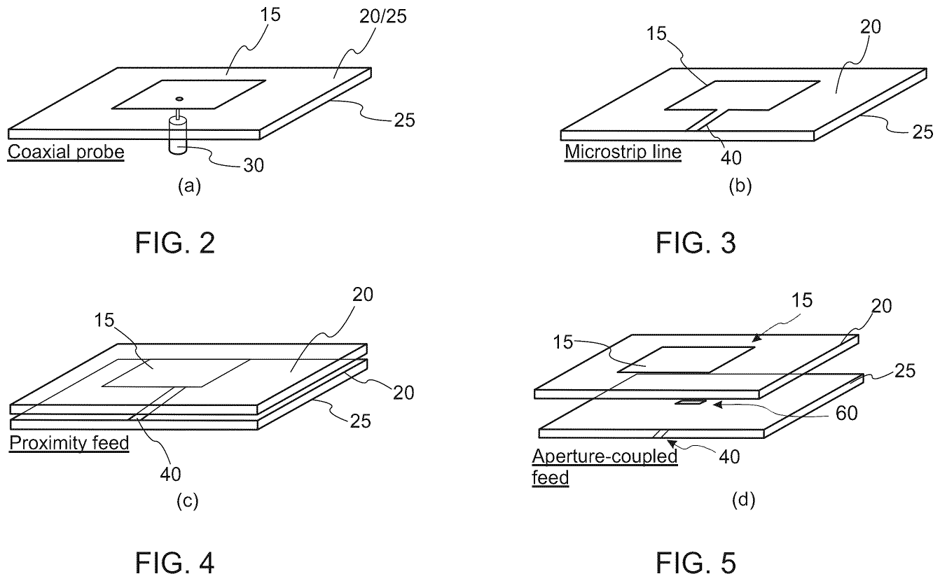

Microstrip patch antennas, in general, have contacting methods which are microstrip line feed methods or coaxial plane feed methods. Non-contacting methods are aperture coupled feed and proximity coupled feed methods. In summary, there are four types of feeding techniques in a microstrip and FIGS. 2 to 5 show these different patch antennae feeding methods. Additionally, table 1 below summarizes feeding technique advantages, indicated by (+), or disadvantages, indicated by (−).

A metal patch antenna with a coaxial probe feed is shown in FIG. 2. Again, the metal patch 15, the dielectric substrate 20, and the ground plane 25 are indicated in FIG. 2. As can be seen, a coaxial probe 30 is provided and shown in FIG. 2. The coaxial probe 30 feeds the antenna patch 15 in use via a contacting method as mentioned above, i.e., by directly contacting the patch 15 and feeding RF power to the patch 15 via the coaxial probe 30.

A metal patch antenna 15 with a microstrip line feed 40 is shown in FIG. 3. This is also a contacting method of feeding the antenna. In this type of device, a conducting strip 40 is connected directly to the edge of the microstrip patch 15. The patch 15 is wider than the conducting strip 40. The feed can therefore be etched onto the same dielectric substrate 20 to provide a planar structure as shown in FIG. 3.

A metal patch antenna 15 with a proximity coupled feed is shown in FIG. 4. Proximity coupled feed techniques are also called electromagnetic coupling techniques. In such devices, two dielectric substrates 20 are provided and the feed line is provided so as to be positioned between the two substrates as shown in FIG. 4. The radiating patch 15 is provided on the top of the upper substrate 20. This also uses a microstrip line 40, however, this is a non-contacting method, as the microstrip 40 is not directly touching the patch 15, but instead is embedded in the lower dielectric substrate 20.

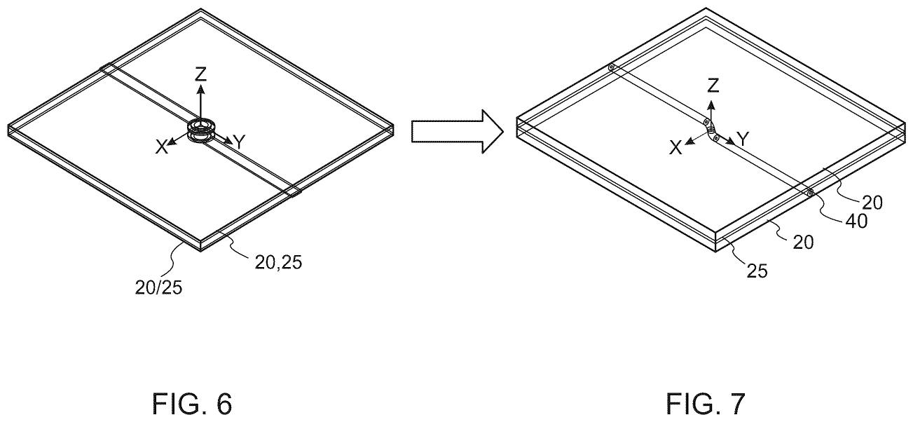

Finally, a metal patch 15 with an aperture coupled feed 60 is shown in FIG. 5. In this example the microstrip line 40 lies on the dielectric substrate 25 and the slot 60 is on the ground plane 35. This is a non-contacting feed method with the aperture coupled feeding technique, the input signal, or microstrip line 40 coupled to the radiating patch 15 through the slot 60 that is provided in the ground plane 25.

In all the examples, the goal of the feeding is to transmit as much RF power as possible to the antenna patch.

TABLE 1

| | FIG. 2 | FIG. 3 | FIG. 4 | FIG. 5 |
|---|---|---|---|---|
| | Coaxial/ | Microstrip- | Proximity- | Slot- |
| | probe feed | line feed | coupled feed | coupled feed |
| Spurious feed | (+) | (−) | (+) | (++) |
| radiation | Low | High | Low | Very low |
| Reliability | (−) | (++) | (+) | (+) |
| | Poor - due to | Very good | Good | Good |
| | soldering | | | |
| Ease of | (−) | (+) | Medium | medium |
| fabrication | Low -due to | High | | |
| | soldering and | | | |
| | substrate | | | |
| | drilling | | | |
| Bandwidth | Low | Low | Medium | High |
| Power losses | (+) | (−) | (−) | (−) |
| | Low | Medium/high | Medium/high | Medium/high |
| Disturbances | (+) | (−) | (−) | (−) |
| immunity | High | Low | Low | Low |
| Used in PCB | (−) | (+) | (+) | (+) |
| | No | Yes | Yes | Yes |

As can be seen in table 1, the use of a coaxial probe as a feeding technique has many advantages, but cannot be used, at present, in a PCB. The examples described herein therefore aim to provide a new connection system where a coaxial probe feed is compatible for use in a PCB and that also has high reliability and easy fabrication.

A microstrip line 40 with a “via” connection is shown in FIG. 6. Such a solution is used in traditional PCB for transmitting signals. In this example, two grounded substrates, each including a ground plane 25 associated with a dielectric substrate 20 are provided and the microstrip line 40 is provided between the two grounded substrates.

An example of a new connection, or RF patch feeding design, in accordance with one or more embodiments of the present disclosure is shown in FIG. 7. For example, the new connection or RF patch feeding design, as shown in FIG. 7, may use a coax-like connection instead of the traditionally used microstrip. It can be observed by comparing FIGS. 6 and 7 that the new design, as shown in FIG. 7, provides additional benefits in the PCB design. That is, only a single ground plane 25 is required, as shown in FIG. 7. The ground plane 20 of the present disclosure is provided between a first upper dielectric substrate 20 and a second lower dielectric substrate 20. By reducing the number of ground planes 25 required, the PCB complexity is simplified. The connection impedance control is also simplified since it depends only on the geometrical and physical properties of the connection and not by the surrounding environment (i.e., dielectric thickness and electrical permittivity). The new design also shows low losses because there are no discontinuities caused by the via. It also provides protection from external radiations (as the signal is never directly exposed to electromagnetic interference (EMI)).

In addition to this, the coax-like connection size of the present disclosure may be reduced by using dielectric with low permittivity; however, it could be used only for high-speed/antenna feed signal. It is also possible to have coax-like connections of different sizes for easy connection with chips (since the inner connections could potentially be as small as pin size).

Such coax-like connections cannot, at present, be manufactured using traditional (i.e., photolithography) PCB manufacturing techniques. The examples described herein may therefore be created using 3D printing technologies. It has been found that a coax-like connection can be realized using a (1) multi-material, (2) multi-layer 3D printer generating the entire circuit in a (3) single manufacturing step: dielectric and metal parts. In order to achieve this, the technique must be able to deal with both a dielectric and a metal, the structure should be able to build layer by layer, and the metal and dielectric must be added during the same manufacturing step.

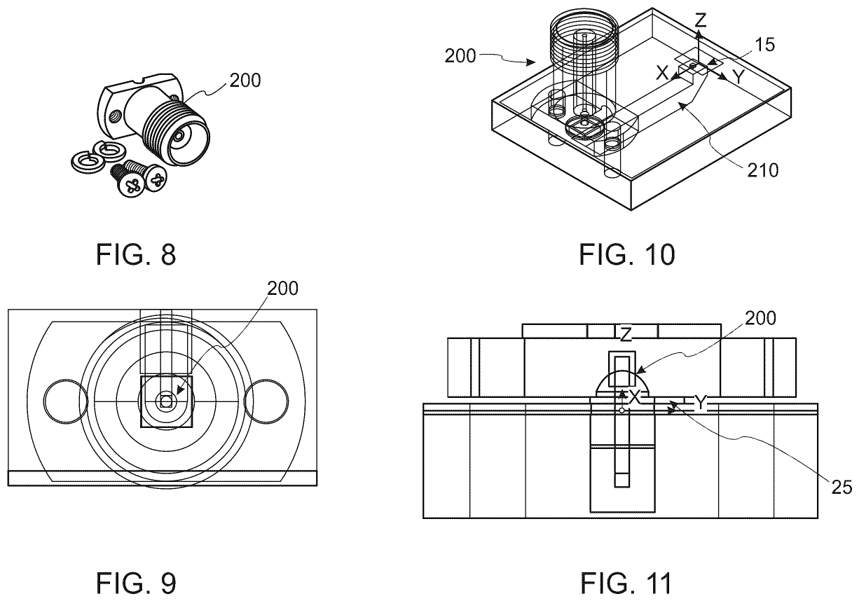

FIGS. 8 to 10 show how a coaxial connection can be fed into the PCB, in accordance with one or more embodiments of the present disclosure. FIG. 8 depicts a connector 200 that may be used in conjunction with the design of FIG. 7. In this example, a signal can be launched using a surface mount connector. For example, a 2.92 mm Jack PCB Compression Surface-Mount Connector CON292001-1 may be used. Other types of connectors may also be used as an alternative.

A top view of the PCB of FIG. 7 is shown in FIG. 9, where the connector pin 200 of FIG. 8 is attached. The connector pin 200 shall be aligned with the coax inner.

FIG. 10 shows a 3D view of the PCB of FIG. 9, in accordance with one or more embodiments of the present disclosure. As can be seen, a coax-like connection 210 connects the surface mount connector 200 to the metal patch 15 of the antenna. A front view of this is shown in FIG. 11, in accordance with one or more embodiments of the present disclosure. As shown in FIG. 11, it can be seen that the connector pin 200 is at the same level as the dielectric layer 20.

FIG. 11 depicts a side, cross sectional, view of the PCB of FIGS. 7, 9 and 10, in accordance with one or more embodiments of the present disclosure. This is a functional block diagram showing the internal connections of the PCB that can be used for the antenna. This can have a working range in the GHz spectrum and in some examples may include a Qorvo®-cmd297P34 analogue phase shifter.

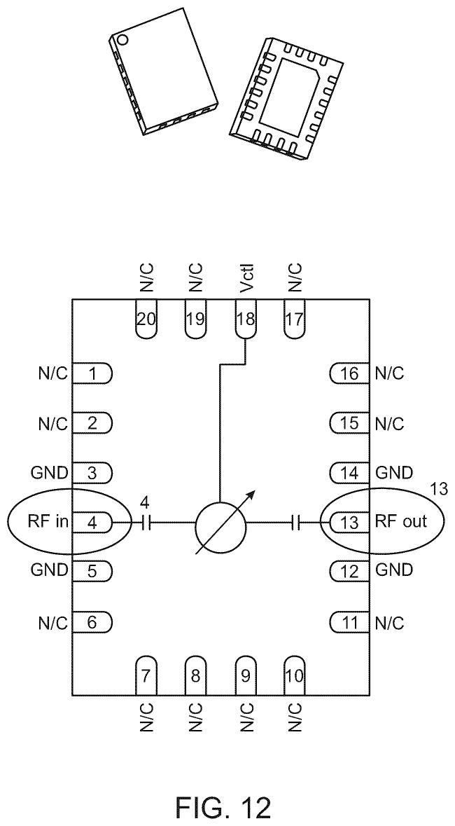

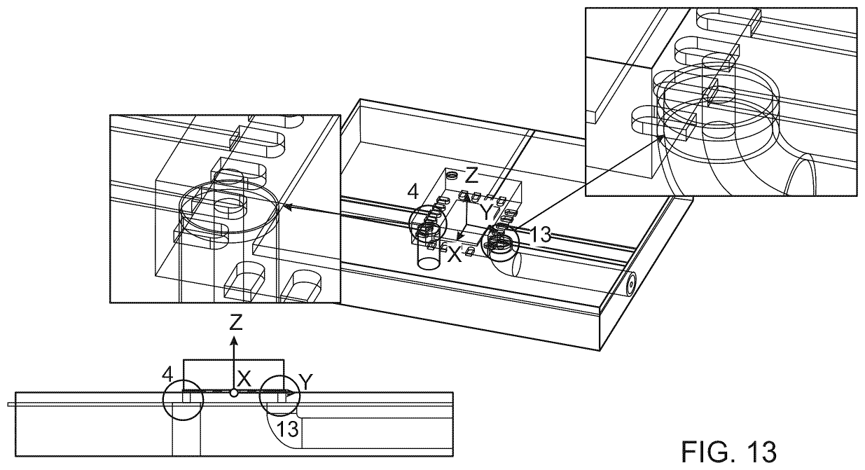

FIG. 12 depicts how the coax-like connection may be fed into the PCB, in accordance with one or more embodiments of the present disclosure. As can be seen FIG. 12, first and second coax pins 4, 13 may be provided on the ground plane or substrate 25 by being embedded therein. The coax pins 4, 13 are shown in FIG. 11. Classical microstrips may be used for connecting direct current (DC) ground or power signals to the coax pins 4, 13. Such coax like connections can be used for high-frequency signals.

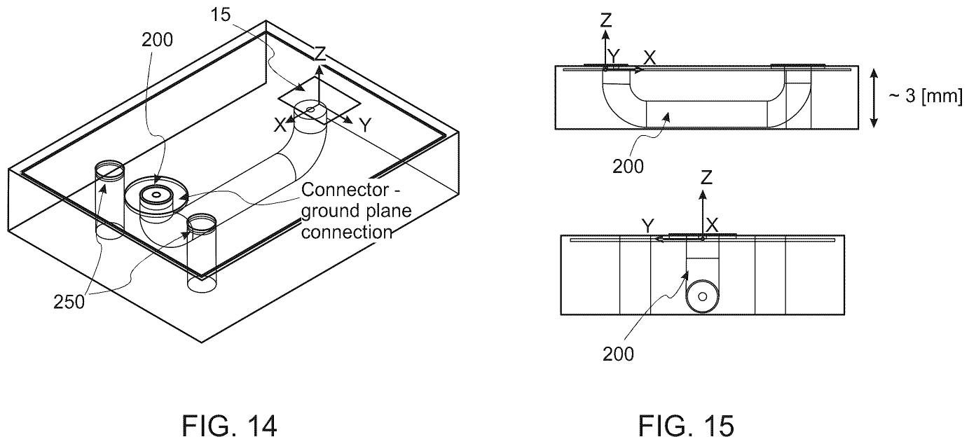

FIG. 14 depicts a top view of a single patch-circular coax-like connection, in accordance with one or more embodiments of the present disclosure. This connection can be designed such that it matches perfectly, or at least almost perfectly, to a surface mount connector, such as that shown in FIG. 8. The patch 15 can be seen in FIG. 14, as well as the coax-like connection, which is extending through the ground substrate 25. Holes 250 are also provided for the connectors. In the example shown in FIG. 14, the patch 15 has been designed for working in the Ku-band. A side view of the coax-like connection is shown in FIG. 14. The depth of the dielectric substrate 25 may be in the region of around a few mm, e.g., 1 to 3 mm. However, other design parameters (e.g., substrate thickness and patch size) may be envisaged. FIG. 15 shows side, cross sectional views of FIG. 14, in accordance with one or more embodiments of the present disclosure.

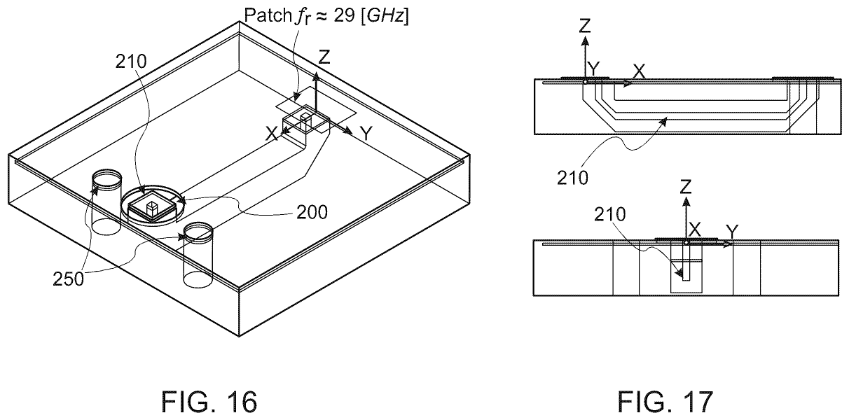

The example shown in FIGS. 16 and 17 again depict a single patch square coax-like connection 210. The same features as discussed above in relation to FIGS. 14 and 15 are provided in these figures too. Such a square coax-like connection can be designed such that it perfectly, or at least almost perfectly, matches a surface of the mount connector. This may also be optimised by using 3D printing for its manufacture.

It is possible to have coax like connections of any section shape, however, the square section coax like connection is most suitable for 3D printing.

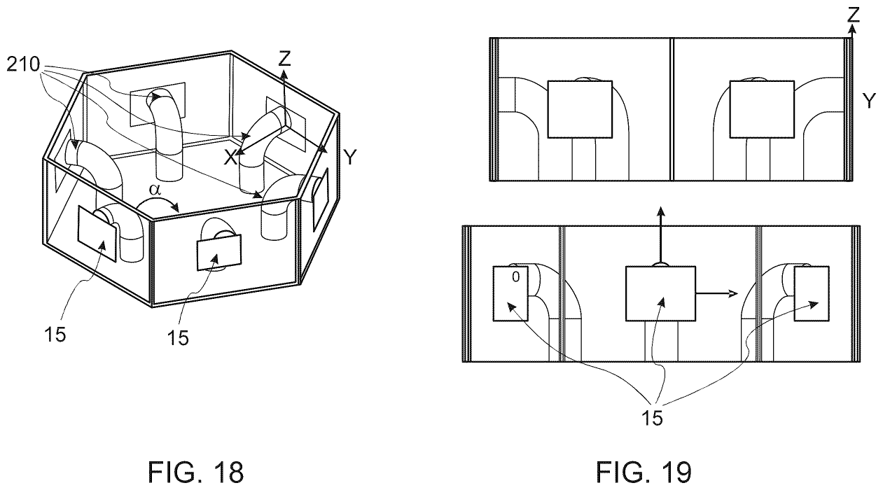

FIG. 18 depicts a hexagonal patch antenna array, in accordance with one or more embodiments of the present disclosure. As can be seen FIG. 18, there may be provided a plurality of patches 15 around the exterior of the antenna array, each having an individual coaxial connection 210 attached thereto. The dielectric support may be different from the coax dielectric. That is, there are two dielectric parts in the design: (a) the dielectric substrate which the patches are lying on and (b) the dielectric in the coax-like connection. The dielectric is characterized by a physical property called dielectric permittivity (among others). It has an impact on the PCB/coax-like connection design. The fact the dielectric in the coax-like and the PCB are different provides an additional degree of freedom in the design. The examples described herein are also not restricted to using a single dielectric and, in some examples, more than one may be used.

In some examples, a phase shifter may be installed in the bottom (e.g., flat part) of the antenna for controlling the array beam. Typically, a phase shifter has 4 in/out so maybe an octagonal antenna is more appropriated. The 3D printing process can deal with whatever angle α and there would be no need to glue different PCB pieces. Although a hexagonal antenna array is shown in FIG. 17, other shaped arrays could also be envisaged, using the same concept.

The new antennas described herein have increased robustness with respect to cross-talk and external radiated interferences, because the external conductor shields them. The techniques used also implement an easy feeding (e.g., probe-feed) technique for microstrip antennas. Power losses are also reduced during signal transmission. Additionally, the new antennas described herein enable new opportunities for an easier design of conformal radiating systems since they can connect microstrip antennas whatever their orientation. There is also an easier microstrip antenna impedance matching (e.g., probe feed), increased signal integrity (e.g., high frequency signal), and less shield external interference, cross-talk. The PCB can also be simplified, due to the fact that there is a reduced number of vias and due to the fact that there is no need to place “ground” microstrip lines between high frequency signals. This, in turn, means that it is easier to control the board thickness.

Although this disclosure has been described in terms of preferred examples, it should be understood that these examples are illustrative only and that the claims are not limited to those examples. Those skilled in the art will be able to make modifications and alternatives in view of the disclosure which are contemplated as falling within the scope of the appended claims.

1. A printed circuit board (PCB) comprising;
a coaxial-like connection, wherein the coaxial-like connection is configured to transmit one or more radio frequency signals.

2. The PCB of claim 1, wherein the coaxial-like connection is manufactured via one or more 3D printing techniques.

3. The PCB of claim 2, wherein the coaxial-like connection is manufactured via an additive manufacturing technique.

4. The PCB of claim 1, further comprising:
an antenna, wherein the antenna comprises:
a first dielectric layer having a first upper surface, a second lower surface opposite the first upper surface, and a metal patch provided on the first upper surface of the first dielectric layer;
a second dielectric layer having an additional first upper surface and an additional second lower surface opposite the additional first upper surface; and
a ground plane provided between the second lower surface of the first dielectric layer and the additional first upper surface of the second dielectric layer,
the coaxial-like connection being provided embedded in the ground plane, the coaxial-like connection being connected to the metal patch to thereby transmit radio frequency power to the metal patch in use.

5. The PCB of claim 4, wherein the ground plane is in direct contact with the second lower surface of the first dielectric layer and in direct contact with the additional first upper surface of the second dielectric layer.

6. The PCB of claim 4, wherein a surface mount connector is provided on and attached to the first upper surface of the first dielectric layer via a mount connector.

7. The PCB of claim 6, wherein the coaxial-like connection connects the surface mount connector to the metal patch.

8. The PCB of claim 7, further comprising:
first and second coax pins embedded in the ground plane, the first and second coax pins being configured to receive and output the one or more RF signals in use.

9. The PCB of claim 3, wherein the PCB is manufactured via an additive manufacturing technique.

10. A method of manufacturing a printed circuit board (PCB) comprising:
forming a coaxial-like connection in a PCB via one or more 3D printing, wherein the coaxial-like connection is configured to transmit one or more radio frequency (RF) signals.

11. The method of claim 10, further comprising:
forming the coaxial-like connection via one or more additive manufacturing techniques.

12. The method of claim 10, further comprising:
forming an antenna for the PCB, wherein the method comprises:
providing a first dielectric layer having a first upper surface and a second lower surface opposite the first upper surface;
providing a metal patch on the first upper surface of the first dielectric layer;
providing a second dielectric layer having an additional first upper surface and an additional second lower surface opposite the additional first upper surface;
providing a ground plane between the second lower surface of the first dielectric layer and the additional first upper surface of the second dielectric layer; and
embedding the coaxial-like connection in the ground plane, and connecting the coaxial-like connection to the metal patch to thereby transmit radio frequency power to the metal patch in use.

13. The method of claim 12, further comprising:
providing the ground plane such that the ground plane is in direct contact with the second lower surface of the first dielectric layer and in direct contact with the additional first upper surface of the second dielectric layer.

14. The method of claim 12, further comprising:
providing and attaching a surface mount connector to the first upper surface of the first dielectric layer via the surface mount connector.

15. The method of claim 14, further comprising:
connecting the coaxial-like connection via the surface mount connector to the metal patch.

16. The method of claim 14, further comprising:
embedding first and second coax pins in the ground plane,
the first and second coax pins being configured to receive and output the one or more RF signals in use.
